(19) United States
(12) Patent Application Publication
(10) Pub. No.: US 2006/0152559 A1
(43) Pub. Date: Jul. 13, 2006

(54) Pattern formation method, method for manufacturing color filter, color filter, method for manufacturing electro-optical device, and electro-optical device

(75) Inventors: Hirofumi Sakai, Suwa-shi (JP); Sadaharu Komori, Suwa-shi (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/316,940

(22) Filed: Dec. 27, 2005

(30) Foreign Application Priority Data
Jan. 11, 2005 (JP) 2005-003423

(51) Int. Cl. B41J 2/17

(52) U.S. Cl. 347/84

(57) ABSTRACT

A pattern formation method includes: forming on a pattern formation surface a barrier for forming a pattern; and discharging in a pattern formation region bounded by the barrier droplets containing a pattern formation material, thereby forming the pattern. A lower limit volume of the droplet is determined based on a width in one direction of the pattern formation region and a contact angle of the droplets with respect to the pattern formation surface, such that a volume of the droplet discharged in the pattern formation region is equal to or greater than the lower limit volume.

### BACKGROUND

1. Technical Field

The present invention relates to a pattern formation method, a method for manufacturing a color filter, a color filter, a method for manufacturing an electro-optical device, and an electro-optical device.

2. Related Art

Known methods for manufacturing organic electroluminescence elements (organic EL elements) employ a liquid phase process, in which a solution of a macromolecular organic material that will constitute the organic EL element is used to coat an element formation region bounded by a barrier. An inkjet method, which is one of these liquid phase processes, involves discharging the solution in the form of microscopic droplets, and therefore allows the formation of finer organic EL elements than other liquid phase processes (such as spin coating).

With an inkjet method, however, if the droplets are discharged into the element formation region (pattern formation region) in too small a volume, the droplets will not spread out and wet the entire pattern formation region. On the other hand, if the droplets are discharged in too large a volume, the droplets will leak out into adjacent pattern formation regions. In other words, this leads to a variance in the shape (pattern shape) of the organic EL layer formed in the pattern formation region, which is problematic.

In view of this, there have been proposals for reducing the variance in pattern shape attributable to the volume of the droplets in such inkjet methods (see JP-A-2000-353594, for example). With JP-A-2000-353594, the shape of the pattern formation region (the width of the pattern formation region, the width of the barrier, and the height of the barrier) is determined on the basis of the diameter of the droplets being discharged. This means that a pattern formation region corresponding to the volume of the droplets is formed, which reduces inadequate wetting by the droplets as well as leakage into adjacent pattern formation regions, and improves the uniformity of the pattern shape.

However, with JP-A-2000-353594, the volume of the droplets is determined solely on the basis of the shape of the pattern formation region, which leads to the following problems.

Inadequate wetting by the droplets and leakage into adjacent pattern formation regions are greatly dependent on the wettability (contact angle) of the droplets with respect to the pattern formation region. For instance, if the droplets have a large contact angle to the bottom part of the pattern formation region, the droplets will not readily spread out to wet the region, so the volume in which the droplets are discharged must be increased. Also, if the contact angle of the droplets to the barrier is low, the droplets will tend to leak out, so the volume in which the droplets are discharged must be decreased.

Therefore, if the volume of the droplets is determined solely by the shape of the pattern formation region, inadequate wetting by the droplets and leakage into adjacent pattern formation regions cannot be sufficiently avoided, and will lead to the problem of variance in pattern shape.

### SUMMARY

It is an advantage of the invention to provide a pattern formation method, a method for manufacturing a color filter, a color filter, a method for manufacturing an electro-optical device, and an electro-optical device, with which the volume of droplets discharged into a pattern formation region is determined based on the wettability of the droplets to this pattern formation region, which improves the uniformity of the pattern shape and in turn productivity.

The pattern formation region of an aspect of the invention includes forming on a pattern formation surface a barrier for forming a pattern; and discharging in a pattern formation region bounded by the barrier droplets containing a pattern formation material, thereby forming the pattern. A lower limit volume of the droplet is determined based on a width in one direction of the pattern formation region and a contact angle of the droplets with respect to the pattern formation surface, such that a volume of the droplet discharged in the pattern formation region is equal to or greater than the lower limit volume.

With this pattern formation method, since the lower limit volume of the droplet discharged in the pattern formation region is determined based on the contact angle of the droplets to the pattern formation surface, the droplets can reliably wet and spread out over the entire width of the pattern formation region in one direction. As a result, likelihood of insufficient wetting by the droplets can be reduced, and the uniformity of the pattern shape can be improved and the uniformity of the pattern shape can be improved.

In this pattern formation method, the lower limit volume is preferably a volume at which a distance between an apex of the droplet discharged in the pattern formation region and the pattern formation surface is expressed as: Wa·{(1−cos θa)/sin θa}, where Wa is the width of the pattern formation region in the one direction, and θa is the contact angle of the droplets with respect to the pattern formation surface.

With this pattern formation method, since the lower limit volume is the volume at which the distance between the apex of a droplet discharged in the pattern formation region and the pattern formation side is Wa·{(1−cos θa)/sin θa}, droplets can be reliably discharged in a volume that allows them to wet and spread out over the entire width of the pattern formation region in the one direction.

In this pattern formation method, the pattern formation surface is rendered lyophilic to the droplets.

With this pattern formation method, the droplets can be discharged in a volume corresponding to the lyophilic property imparted to the pattern formation region, and the uniformity of the pattern shape can be further enhanced.

The pattern formation method includes forming on a pattern formation surface a barrier for forming a pattern; and discharging in a pattern formation region bounded by the barrier droplets containing a pattern formation material, thereby forming the pattern. An upper limit volume of the droplet is determined based on a width of the pattern formation region in one direction, a width of the barrier in the one direction, a distance between the pattern formation surface and an apex of the barrier, and a contact angle of the droplets with respect to the barrier. A volume of the droplet discharged in the pattern formation region is equal to or less than the upper limit volume.

With the pattern formation method of the aspect of the invention, since the upper limit volume of the droplet discharged in the pattern formation region is determined based on the contact angle of the droplets with respect to the barrier, the droplets can be discharged in a volume that can be accommodated within the pattern formation region. As a result, likelihood of leakage of the droplets to outside the pattern formation region can be reduced, and the uniformity of the pattern shape can be improved.

In this pattern formation method, the upper limit volume is preferably a volume at which a distance between an apex of the droplet discharged in the pattern formation region and the pattern formation surface is (Wa+Wb)·{(1−cos θb)/sin θb}+Hb, where Wa is the width of the pattern formation region in the one direction, Wb is the width of the barrier in the one direction, Hb is a thickness of the barrier from the pattern formation side, and θb is the contact angle of the droplets with respect to the pattern formation surface.

With this pattern formation method, since the upper limit volume is the volume at which the distance between the apex of a droplet and the pattern formation surface is (Wa+Wb)·{(1−cos θb)/sin θb}+Hb, the droplets can be discharged in a volume that can be accommodated within the pattern formation region, and likelihood of leakage of the droplets to outside the pattern formation region can be reduced.

In this pattern formation method, the barrier is preferably rendered liquid-repellent with respect to the droplets.

With this pattern formation method, the droplets can be discharged in a volume corresponding to the liquid-repellency imparted to the pattern formation region, and the uniformity of the pattern shape can be further enhanced.

The pattern formation method of still another aspect of the invention includes forming on a pattern formation surface a barrier for forming a pattern; and discharging in a pattern formation region bounded by the barrier droplets containing a pattern formation material, thereby forming the pattern. A lower limit volume of the droplet is determined based on a width of the pattern formation region in a first direction and a contact angle of the droplets with respect to the pattern formation side. An upper limit volume of the droplet is determined based on a width of the pattern formation region in a second direction, a width of the barrier in the second direction, a distance between the pattern formation surface and an apex of the barrier, and a contact angle of the droplets with respect to the barrier. A volume of the droplet discharged in the pattern formation region is equal to or greater than the lower limit volume, and equal to or less than the upper limit volume.

With this pattern formation method, since the lower limit volume of the droplet discharged in the pattern formation region is determined based on the contact angle of the droplets with respect to the pattern formation surface, the droplets can reliably wet and spread out over the entire width of the pattern formation region in the one direction. Furthermore, since the upper limit volume of the droplet discharged in the pattern formation region is determined based on the contact angle of the droplets with respect to the barrier, the droplets can be discharged in a volume that can be accommodated within the pattern formation region. As a result, leakage of the droplets to outside the pattern formation region is less likely to occur, and the uniformity of the pattern shape can be reliably improved.

The pattern formation method of still another aspect of the invention includes forming on a pattern formation surface a barrier for forming a pattern; and discharging in a pattern formation region bounded by the barrier droplets containing a pattern formation material, thereby forming the pattern. Each of the droplets is discharged in the pattern formation region in a volume that satisfies: Wa·{(1−cos θa)/sin θa}≦H≦(Wa+Wb)·{(1−cos θb)/sin θb}+Hb, where Wa is a width of the pattern formation region in one direction, Wb is a width of the barrier in the one direction, Hb is a thickness of the barrier from the pattern formation surface, θb is a contact angle of the droplets with respect to the pattern formation surface, and H is a distance between an apex of the droplet discharged in the pattern formation region and the pattern formation surface.

With this pattern formation method, since the distance between the apex of a droplet and the pattern formation surface, in other words the volume of the droplets, is determined based on the contact angle of the droplets with respect to the pattern formation surface and the barrier, the droplets can be discharged in a volume that can be accommodated within the pattern formation region and that allows the droplets to wet and spread out over the pattern formation surface. As a result, likelihood of leakage of the droplets to outside the pattern formation region can be reduced, and the uniformity of the pattern shape can be improved.

The method of still another aspect of the invention for manufacturing a color filter is a method for manufacturing a color filter in which a color filter layer is formed on a transparent substrate, wherein the color filter layer is formed by the above-mentioned pattern formation method.

With the method of this aspect of the invention for manufacturing a color filter, a color filter layer of more uniform shape can be formed, and the color filter productivity can be increased.

The color filter of still another aspect of the present invention is manufactured by the above-mentioned method for manufacturing a color filter.

With the color filter of this aspect of the invention, the shape of the color filter layer can be made more uniform, and the productivity thereof can be increased.

The method of still another aspect of the present invention for manufacturing an electro-optical device is a method for manufacturing an electro-optical device in which a light emitting element is formed on a transparent substrate, wherein the light emitting element is formed by the above-mentioned pattern formation method.

With the method of this aspect of the present invention for manufacturing an electro-optical device, a light emitting element can be formed in a more uniform shape, and the productivity of an electro-optical device can be increased.

The electro-optical device of still another aspect of the invention is manufactured by the above-mentioned method for manufacturing an electro-optical device.

With the electro-optical device of this aspect of the invention, the shape of a light emitting element can be made more uniform, and the productivity thereof can be increased.

### BRIEF DESCRIPTION OF THE DRAWINGS

FIG. 1 is a simplified plan view of an organic EL display that is an embodiment of the present invention;

FIG. 2 is a simplified plan view of pixels in the same;

FIG. 3 is a simplified cross section of the control element formation region in the same;

FIG. 4 is a simplified cross section illustrating the control element formation region in the same;

FIG. 5 is a simplified cross section illustrating the light emitting element formation region in the same;

FIG. 6 is a simplified cross section illustrating the light emitting element formation region in the same;

FIG. 7 is a flowchart of the steps of manufacturing an electro-optical device in the same;

FIG. 8 is a diagram illustrating the steps of manufacturing an electro-optical device in the same;

FIG. 9 is a diagram illustrating the steps of manufacturing an electro-optical device in the same;

FIG. 10 is a diagram illustrating the light emitting element formation region in a modification; and

FIG. 11 is a cross section of the light emitting element formation region in a modification.

### DESCRIPTION OF EXEMPLARY EMBODIMENTS

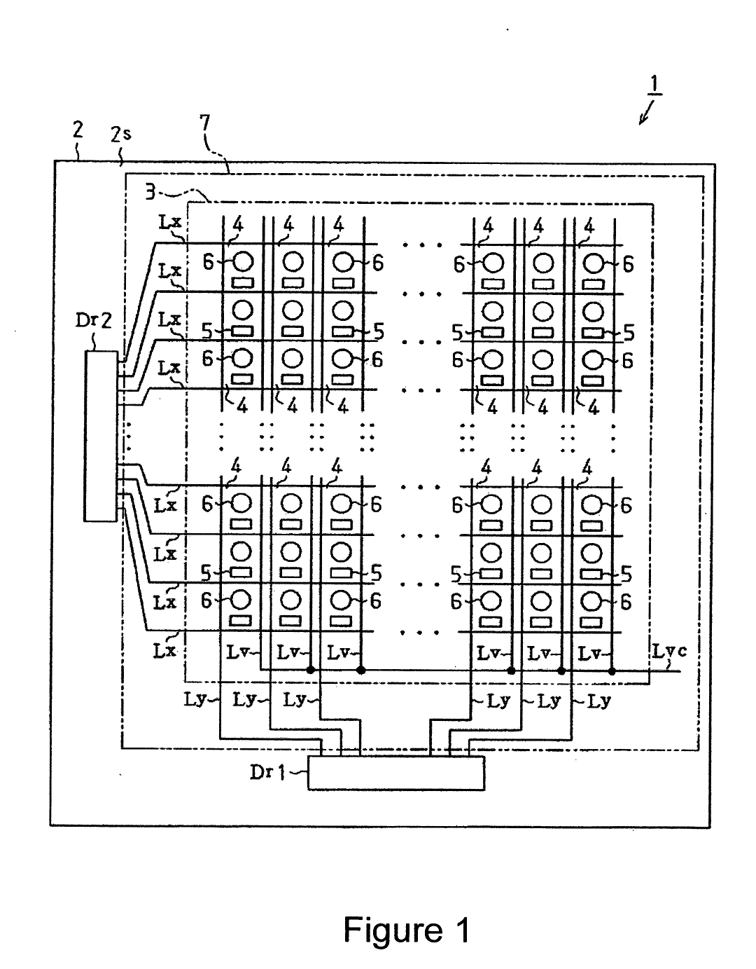

Embodiments of the present invention will now be described through reference to FIGS. 1 to 9. FIG. 1 is a simplified plan view of an organic electroluminescence display (organic EL display) that serves as an electro-optical device.

As shown in FIG. 1, an organic EL display 1 is equipped with a transparent substrate 2. The transparent substrate 11 is a non-alkaline glass substrate formed in the shape of a square, and a square element formation region 3 is formed on one side surface thereof (element formation side 2s (the pattern formation side), which is the front side in FIG. 1).

In this element formation region 3, a plurality of data lines Ly are formed at a specific spacing and extending in the vertical direction (column direction). The data lines Ly are electrically connected to a data line drive circuit Dr1 disposed on the lower side of the transparent substrate 2. The data line drive circuit Dr1 produces a data signal on the basis of display data supplied from an external apparatus (not shown), and outputs this data signal at a specific timing to the data lines Ly corresponding to the data signal.

In the element formation region 3, a plurality of power lines Lv extending in the same column direction as the data lines Ly are provided to the data lines Ly at a specific spacing. The power lines Lv are electrically connected to a common power line Lvc formed on the lower side of the element formation region 3, and drive power produced by a power supply voltage production circuit (not shown) is supplied to the power lines Lv.

A plurality of scanning lines Lx extending in the direction perpendicular to the data lines Ly and the power lines Lv (the row direction) are formed at a specific spacing in the element formation region 3. The scanning lines Lx are electrically connected to a scanning line drive circuit Dr2 formed on the left side of the transparent substrate 2. The scanning line drive circuit Dr2 selectively drives specific scanning lines Lx from among the plurality of scanning lines Lx at a specific timing on the basis of a scanning control signal supplied from a control circuit (not shown), and outputs a scanning signal to the scanning lines Lx.

A plurality of pixels 4 arranged in a matrix are formed by connecting to the corresponding data lines Ly, power lines Lv, and scanning lines Lx where the data lines Ly and the scanning lines Lx intersect. A square control element formation region 5 and a circular light emitting element formation region 6 are delineated within each of the pixels 4, as shown in FIG. 1.

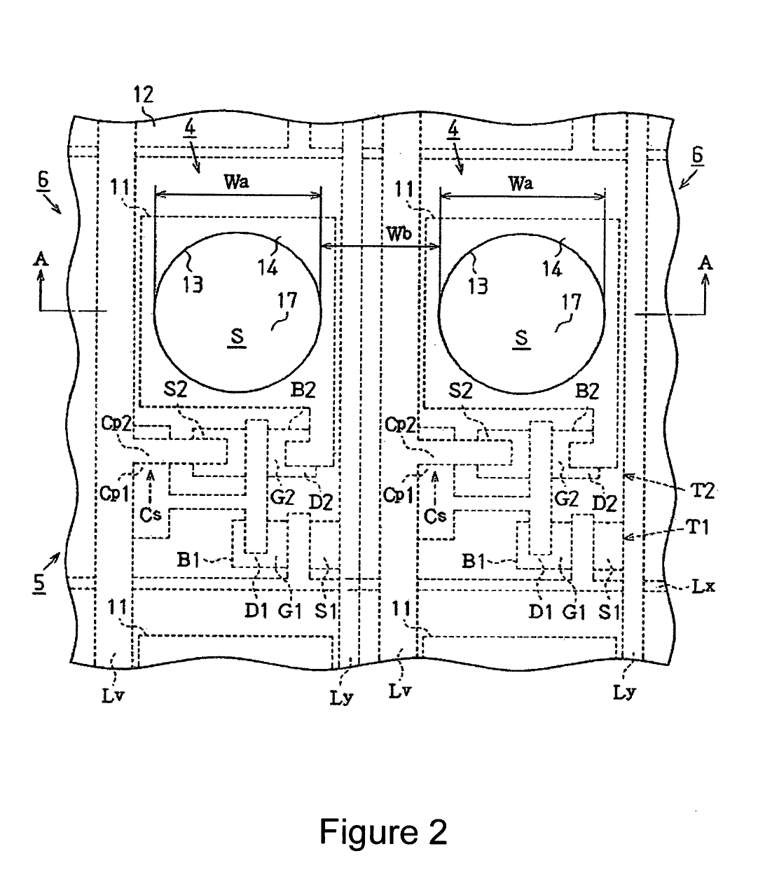

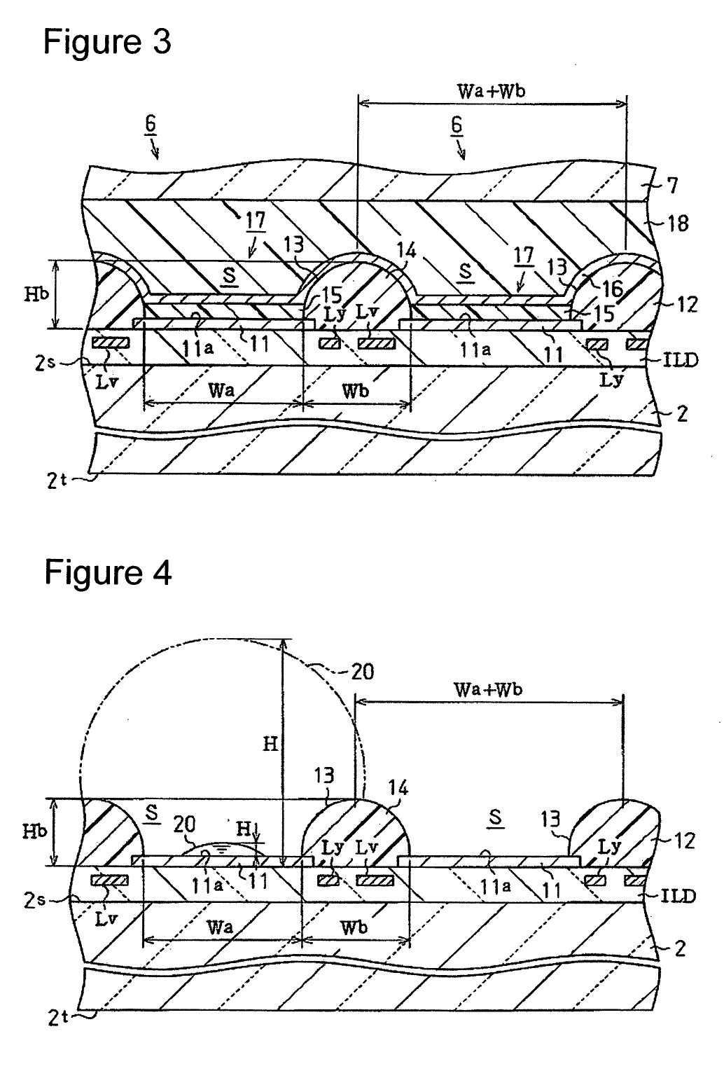

The structure of the pixels 4 will now be described. FIG. 2 is a simplified plan view of the layout of the pixels 4. FIG. 3 is a simplified cross section of pixels 4 along the one-dot chain line in FIG. 2. First the structure of the control element formation regions 5 of the pixels 4 will be described.

As shown in FIG. 2, a control element formation region 5 is formed on the lower side of each of the pixels 4, and a switching transistor T1, a drive transistor T2, and a holding capacitor Cs are formed in each control element formation region 5.

The switching transistor T1 is a polysilicon thin film transistor (TFT), and is equipped with a polysilicon channel film (first channel film B1) having a first channel region G1, a first source region S1, and a first drain region D1. The first channel region G1, first source region S1, and first drain region D1 are electrically connected to the corresponding scanning line Lx, data line Ly, and holding capacitor Cs, respectively.

The drive transistor T2, just like the switching transistor T1, is a polysilicon channel film (second channel film B2) having a second channel region G2, a second source region S2, and a second drain region D2. The second channel region G2, second source region S2, and second drain region D2 are electrically connected to a lower electrode Cp1 of the holding capacitor Cs (the first drain region D1 of the switching transistor T1), an upper electrode Cp2 of the holding capacitor Cs, and an anode 11 (discussed below) of the light emitting element formation region 6, respectively.

The holding capacitor Cs is a capacitor having an insulating film ILD (see FIG. 3) serving as a capacitance film between the lower electrode Cp1 and the upper electrode Cp2, and the upper electrode Cp2 is electrically connected to the corresponding power line Lv. The insulating film ILD (see FIG. 3), which is composed of a silicon oxide film or the like, is formed between the layers and lines of the wiring Lx, Ly, and Lv, and the layers and lines are electrically insulated by this insulating film ILD.

When the scanning line drive circuit Dr2 successively inputs scanning signals through the scanning lines Lx to the first channel regions G1 (line-order scanning), the selected switching transistors T1 are switched on as long as they are selected. When the switching transistor T1 is switched on, the data signal outputted from the data line drive circuit Dr1 is supplied through the corresponding data line Ly and the switching transistor T1 to the lower electrode Cp1 of the holding capacitor Cs. When the data signal is supplied to the lower electrode Cp1, the holding capacitor Cs stores a charge relative to that data signal in the capacitance film. Then, when the switching transistor T1 is switched off, a drive current relative to the charge stored in the holding capacitor Cs is supplied through the drive transistor T2 to the anode 11 of the light emitting element formation region 6.

Next, the structure of the light emitting element formation regions 6 will be described.

As shown in FIG. 2, a light emitting element formation region 6 is formed on the upper side of each of the pixels 4. As shown in FIG. 3, the anode 11 is formed as a transparent electrode on the upper layer of the insulating film ILD in the light emitting element formation region 6. The anode 11 is formed from a lyophilic material such as ITO that is lyophilic (hydrophilic) to droplets 20 (discussed below). One end of the anode 11 is electrically connected to the second drain region D2 of the drive transistor T2.

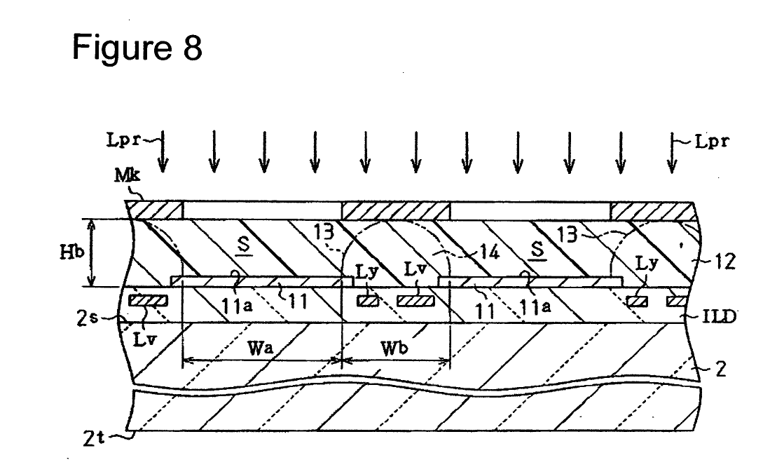

As shown in FIG. 3, a barrier layer 12 that insulates the anodes 11 from each other is formed on the upper layer of the anode 11. The barrier layer 12 is an organic layer formed in a barrier thickness of Hb, and is formed of a fluororesin or other such liquid-repellent material that will repel the droplets 20 (discussed below). Also, the barrier layer 12 is formed from what is called a positive photosensitive material, which when exposed to exposure light Lpr (see FIG. 8) of a specific wavelength, only the exposed portion becomes soluble in a developing solution such as an alkaline solution. In this embodiment, the above-mentioned barrier thickness Hb is 2 μm.

A receptacle hole 13 that opens upward in an arced cross sectional shape is formed in the approximate center of the anode 11 in the barrier layer 12. As shown in FIG. 2, the receptacle hole 13 is formed in a circular shape when seen in plan view, and its inside diameter on the anode 11 side thereof is the wetting width Wa. Also, the receptacle holes 13 are formed such that the shortest distance between two receptacle holes 13 adjacent in the row direction (the direction in which the scanning lines Lx are formed) will be the barrier width Wb. Forming the receptacle hole 13 in the barrier layer 12 forms a barrier 14 that surrounds the top side of the anode 11. As a result of the top side of the anode 11 being thus surrounded by the barrier 14, a landing surface 11 a is demarcated on the top side of the anode 11.

Therefore, the inside diameter of the landing surface 1 a is formed by the inside diameter of the receptacle hole 13 on the anode 11 side, that is, by the wetting width Wa. The thickness of the barrier 14 from the top side of the anode 11 is formed by the thickness of the barrier layer 12, that is, by the barrier thickness Hb, and the width on the anode 11 side is formed by the barrier width Wb. In other words, the layout pitch of the barrier 14 (the landing surface 11a) in the row direction thereof is a pitch width equal to the sum of the wetting width Wa and the barrier width Wb.

In this embodiment, the wetting width Wa is set at 50 μm and the barrier width Wb at 25 μm, and the layout pitch of the barrier 14 (the landing surface 11a) is set at 75 μm. The upper side of the anode 11 is surrounded by the barrier 14 and the landing surface 11a, which forms an organic electroluminescence layer formation region (organic EL layer formation region S) as a pattern formation region.

An organic electroluminescence layer (organic EL layer 15) is formed as a pattern within this organic EL layer formation region S and on the upper side of the landing surface 11a. This organic EL layer 15 is an organic compound layer composed of two layers: a hole transport layer and a light emitting layer.

As shown in FIG. 4, the organic EL layer 15 is formed by forming a droplet 20 containing an organic EL layer formation material (as a pattern formation material) within the organic EL layer formation region S, and drying and solidifying this droplet 20.

Accordingly, if the droplet 20 is formed in too small a volume in the organic EL layer formation region S, as indicated by the solid line in FIG. 4, the droplet 20 will not wet and spread out over the entire landing surface 11a, and will instead stay in just part of the landing surface 11a (such as in the center of the landing surface 11a). Conversely, if the volume of the droplet 20 is too large, as indicated by the two-dot chain line in FIG. 4, part of the droplet 20 will leak past the barrier 14 into an adjacent organic EL layer formation region S. This results in variance in the thickness of the organic EL layer 15 and so forth, which leads to the problem of non-uniform light emission brightness of the organic EL layer 15.

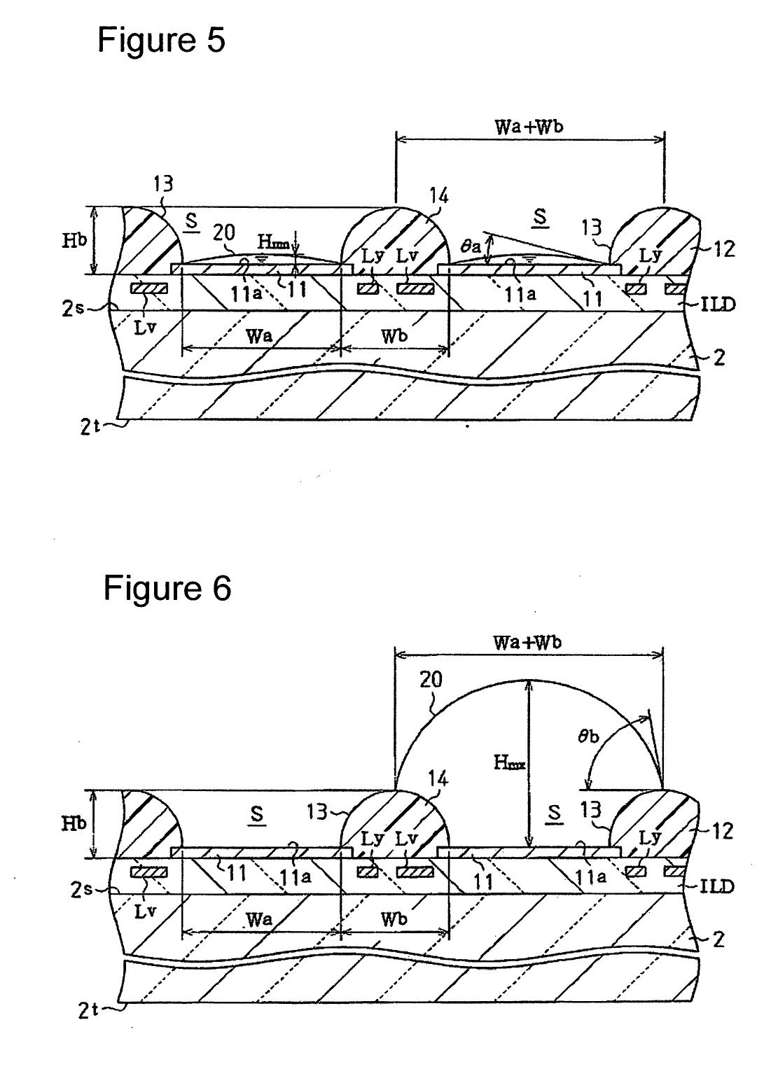

The wetting and spreading of the droplets 20, and their leakage into adjacent organic EL layer formation regions S, are greatly affected by the contact angle of the droplets 20 with respect to the landing surface 11a (landing surface contact angle θa; see FIG. 5) and by the contact angle of the droplets 20 to the barrier 14 (barrier contact angle θb; see FIG. 6).

For instance, the smaller is the landing surface contact angle θa, the more readily will the droplets 20 wet and spread out over the entire landing surfaces 11a, and the organic EL layer 15 can be formed with a smaller amount of droplets 20. Also, the larger is the barrier contact angle θb, the larger is the amount in which the droplets 20 can be accommodated in the organic EL layer formation regions S.

In view of this, the inventors discovered if the surface of the droplet 20 is made to approximate a spherical surface, the lower limit volume at which the droplet 20 will wet and spread out over the entire landing surface 11a, and the upper limit volume at which the droplet 20 will not leak into an adjacent organic EL layer formation region S, can be determined on the basis of the landing surface contact angle θa and barrier contact angle θb.

Specifically, as shown in FIG. 5, when the outer periphery of the droplet 20 coincides with the outer edge of the landing surface 11a, if the surface of the droplet 20 approximates a spherical surface, then the distance between the apex of the droplet 20 and the landing surface 11a (the minimum allowable droplet thickness Hmn) can be found from the following equation using the wetting width Wa (an example of the width of the pattern formation region in the first direction) and the landing surface contact angle θa.
Hmn=Wa·{(1−cos θa)/sin θa}

Therefore, the lower limit volume at which the droplet 20 will wet and spread out over the entire landing surface 11 a can be determined on the basis of the minimum allowable droplet thickness Hmn (the wetting width Wa and the landing surface contact angle θa).

Meanwhile, as shown in FIG. 6, when the surface of the droplet 20 reaches the apex of the barrier 14, if the surface of the droplet 20 approximates a spherical surface, then the distance between the apex of the droplet 20 and the landing surface 11a (the maximum allowable droplet thickness Hmx) can be found from the following equation using the wetting width Wa (an example of the width of the pattern formation region in the second direction), the barrier width Wb (an example of the width of the barrier in the second direction), and the barrier contact angle θb.
Hmx=(Wa+Wb)·{(1−cos θb)/sin θb}+Hb

Therefore, the upper limit volume at which the droplet 20 will not leak into an adjacent organic EL layer formation region S can be determined on the basis of the maximum allowable droplet thickness Hmx (the wetting width Wa, the barrier width Wb, and the barrier contact angle θb).

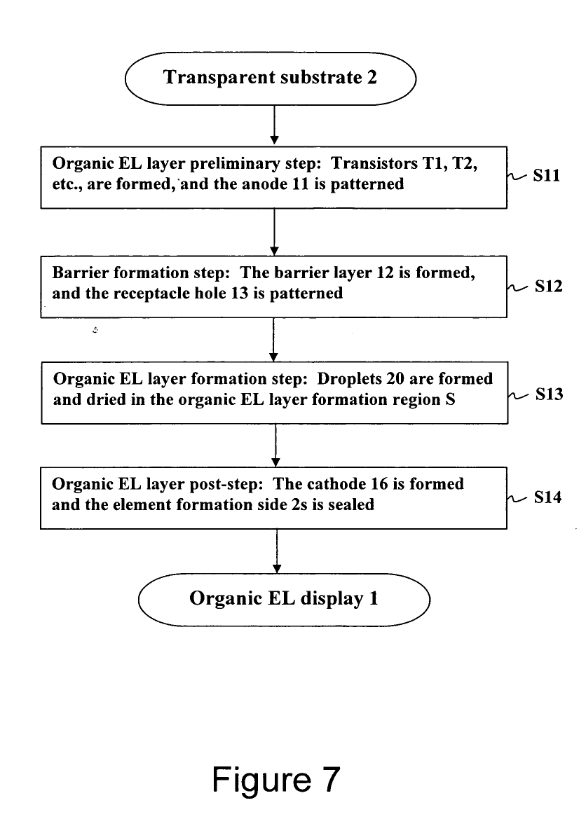

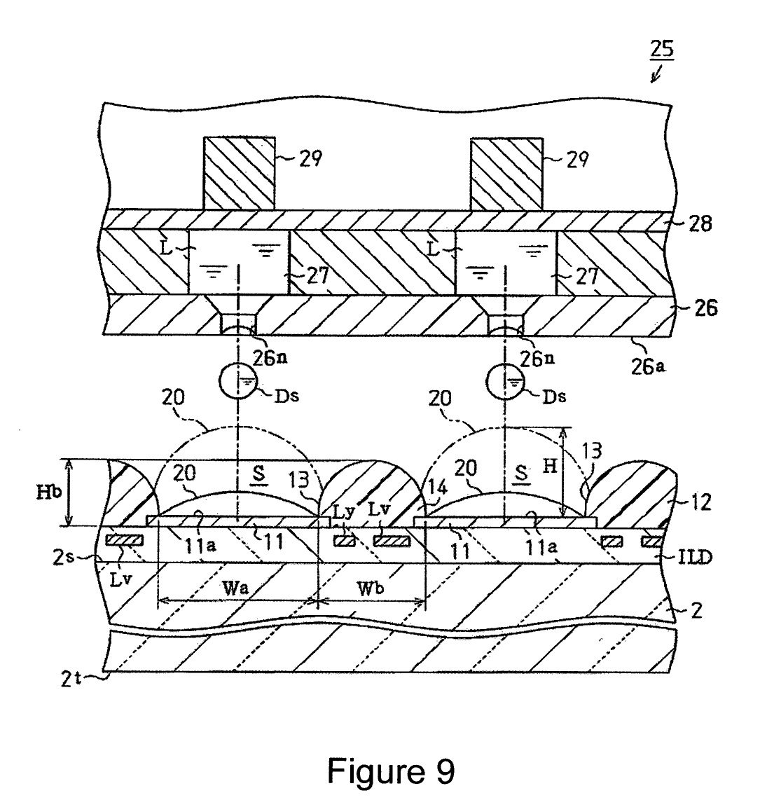

With the present invention, in a droplet formation step (discussed below; step S13 in FIG. 7), the landing surface contact angle θa and the barrier contact angle θb are measured ahead of time, and the distance between the apex of the droplet 20 and the landing surface 1 a (the droplet height H; see FIG. 9) is set to be less than or equal to the maximum allowable droplet thickness Hmx, and to be greater than or equal to the minimum allowable droplet thickness Hmn. Specifically, the volume of the droplet 20 is set to be greater than or equal to the lower limit volume and less than or equal to the upper limit volume.

Incidentally, if the droplet 20 is discharged in the organic EL layer formation region S in this embodiment (formed at a barrier thickness Hb of 2 μm, a wetting width Wa of 50 μm, and a barrier width Wb of 25 μm) such that the landing surface contact angle θa is 15° and the barrier contact angle θb is 80°, the minimum allowable droplet thickness Hmn will be 6.6 μm and the maximum allowable droplet thickness Hmx will be 64.9 μm.

The organic EL layer 15 in this embodiment has light emitting layers that emits light of a corresponding color, namely, a red light emitting layer that emits red light, or a green light emitting layer that emits green light, or a blue light emitting layer that emits blue light.

As shown in FIG. 3, a cathode 16 composed of an optically reflective metal film, such as aluminum, is formed on the upper side of the barrier layer 15. The cathode 16 is formed so as to cover the entire surface of the element formation side 2s of the element formation region 3, and supplies potential for all of the light emitting element formation regions 6 shared by the pixels 4. In this embodiment, an organic electroluminescence element (organic EL element 17) is constituted as a light emitting element by the anode 11, the organic EL layer 15, and the cathode 16.

An adhesive layer 18 composed of an epoxy resin or the like is formed on the upper side of the cathode 16, and a sealing substrate 7 that covers the element formation region 3 is applied via this adhesive layer 18. The sealing substrate 7 is a non-alkaline glass substrate, and serves to prevent the oxidation and the like of the organic EL elements 17, the wiring lines Lx, Ly, and Lv, and so forth.

When drive current corresponding to a data signal is supplied to the anode 11, the organic EL layer 15 emits light at a brightness corresponding to this drive current. Here, the light emitted from the organic EL layer 15 toward the cathode 16 side (the upper side in FIG. 4) is reflected by the cathode 16. Accordingly, almost all of the light emitted from the organic EL layer 16 is transmitted through the anode 11, the insulating film ILD, and the transparent substrate 2, and is emitted outward from the back (the display side 2t) of the transparent substrate 11. Specifically, an image based on the data signal is displayed on the display side 11b of the organic EL display 10.

Method for Manufacturing Organic EL Display 1

Next, the method for manufacturing the organic EL display 1 will be described. FIG. 7 is a flowchart illustrating the method for manufacturing the organic EL display 1, and FIGS. 8 and 9 are diagrams illustrating this method for manufacturing the organic EL display 1.

As shown in FIG. 7, first an organic EL layer preliminary step (step S11) is performed, in which the transistors T1 and T1, the wiring lines Lx, Ly, Lv, and Lvc, and the insulating film ILD are formed on the element formation side 2s of the transparent substrate 2 by known manufacturing technology.

As shown in FIG. 7, when the organic EL layer preliminary step is complete, a barrier formation step is performed (step S12), in which the anode 11 and the barrier 14 are formed on the insulating film ILD. Specifically, a transparent conductive film that is optically transmissive, such as ITO, is deposited over the entire upper side of the insulating film ILD, and as shown in FIG. 8, this transparent conductive film is patterned to form the anode 11, which electrically connects with the second drain region D2 (see FIG. 2). When the anode 11 has been formed, the entire upper side of the anode 11 and the insulating film ILD is coated with a photosensitive polyimide resin or the like to form the barrier layer 12, whose film thickness is the barrier thickness Hb. Developing is then performed by exposing the barrier layer 12 at a position across from the anode 11 to exposure light Lpr of a specific wavelength through a mask Mk, which results in the patterning of the receptacle hole 13.

This forms the barrier 14, whose thickness from the top side of the anode 11 is the barrier thickness Hb, and whose width on the anode 11 side is the barrier width Wb. Then, the landing surface 11a, which is surrounded by the barrier 14 and whose inside diameter is the wetting width Wa, is demarcated on the top side of the anode 11, and the organic EL layer formation region S is formed so as to be surrounded by the barrier 14 and the landing surface 11a.

As shown in FIG. 7, when the barrier 14 has been formed (step S12), an organic EL layer formation step is performed (step S13), in which a droplet 20 containing an organic EL layer formation material is formed in the organic EL layer formation region S, thereby forming the organic EL layer 15. FIG. 9 is a diagram illustrating the organic EL layer formation step.

First, the structure of the droplet discharge apparatus used to form the droplet 20 will be described. As shown in FIG. 9, a liquid discharge head 25 that constitutes the droplet discharge apparatus in this embodiment is equipped with a nozzle plate 26. Numerous nozzles 26n for discharging a functional liquid L in which an organic EL layer formation material has been dissolved are formed facing upward on the bottom side (the nozzle formation side 26a) of this nozzle plate 26. A functional liquid supply chamber 27 that communicates with a functional liquid reservoir (not shown) and allows the functional liquid L to be supplied to the nozzles 26n is formed on the upper side of the nozzles 26n. A diaphragm 28 that vibrates reciprocally up and down and expands and contracts the volume inside the functional liquid supply chamber 27 is provided on the upper side of the functional liquid supply chamber 27. A piezoelectric element 29 that vibrates the diaphragm 28 by expanding and contracting vertically is provided on the upper side of each diaphragm 28 at a position across from the functional liquid supply chamber 27.

As shown in FIG. 9, a transparent substrate 2 conveyed to the droplet discharge apparatus is positioned with its element formation side 2s parallel to the nozzle formation side 26a and with the center of the landing surface 11a disposed directly under each of the nozzles 26n.

When a drive signal for forming the droplet 20 is inputted to the droplet discharge head 25, the piezoelectric element 29 expands or contracts according to this drive signal, thereby increasing or decreasing the volume of the functional liquid supply chamber 27. If the volume of the functional liquid supply chamber 27 decreases here, the functional liquid L is discharged as a microscopic lower layer droplet Ds from each of the nozzles 26n in an amount corresponding to the reduction in volume. The discharged microscopic lower layer droplets Ds land on each of the corresponding landing surfaces 11a. When the volume of the functional liquid supply chamber 27 then increases, the functional liquid L is supplied from a functional liquid reservoir (not shown) into the functional liquid supply chamber 27 in an amount equal to the increase in volume. In other words, the droplet discharge head 25 discharges the required volume of functional liquid L toward the corresponding organic EL layer formation region S by means of the expansion and contraction of the functional liquid supply chamber 27.

Here, a volume (target volume) at which the distance between the apex of the droplet 20 and the landing surface 11 a (target droplet thickness H; see FIG. 9) will be less than or equal to the above-mentioned maximum allowable droplet thickness Hmx and greater than or equal to the minimum allowable droplet thickness Hmn is set in the droplet discharge head 25 as the volume to be discharged, on the basis of the landing surface contact angle θa and barrier contact angle θb measured ahead of time. In other words, the volume of the droplet 20 is set to a volume (target volume) that is greater than or equal to the above-mentioned lower limit volume and less than or equal to the upper limit volume. This avoids insufficient wetting and spreading by the droplets, and leakage into adjacent organic EL layer formation regions S, and allows the droplets 20 to be formed in the same volume (target volume) as each of the organic EL layer formation regions S.

When the droplet 20 has been formed, the transparent substrate 2 (droplet 20) is placed under a specific reduced pressure to evaporate the solvent component of the droplet 20 and form the organic EL layer 15. This forms the organic EL layer 15 in a uniform shape, according to the amount of uniform wetting and spreading over the entire top side of the landing surface 11a, and according to the extent to which leakage into adjacent organic EL layer formation regions S is prevented.

As shown in FIG. 7, when the organic EL layer 15 has been formed (step S13), an organic EL layer post-step (step S14) is performed, in which the cathode 16 is formed over the organic EL layer 15 and the barrier layer 12, and the pixel 4 is sealed. Specifically, the cathode 16 composed of a metal film such as aluminum is deposited over the entire top side of the organic EL layer 15 and the barrier layer 12, forming an organic EL element 17 composed of the anode 11, the organic EL layer 15, and the cathode 16. When the organic EL element 17 has been formed, an adhesive layer 18 is formed by coating the entire top side of the cathode 16 (pixel 4) with an epoxy resin or the like, and the sealing substrate 7 is applied to the transparent substrate 2 via this adhesive layer 18.

The result of the above is that an organic EL display 1 in which the organic EL layer 30 has a uniform shape can be manufactured.

Next, the effects of this embodiment, constituted as above, will be described.

(1) With the above embodiment, the surface of the droplet 20 was made to approximate a spherical surface, and the thickness of the droplet 20 from the landing surface 11a when the outer periphery of the droplet 20 coincided with the outer edge of the landing surface 11a (the minimum allowable droplet thickness Hmn) was found from the shape of the organic EL layer formation region S (the wetting width Wa) and the landing surface contact angle θa. The lower limit volume to be discharged into the organic EL layer formation region S was determined on the basis of the minimum allowable droplet thickness Hmn, and the volume (target volume) of the droplet 20 to be discharged into the organic EL layer formation region S was set to be greater than or equal to this lower limit volume.

Therefore, the discharged droplet 20 is able to wet and spread out over the entire wetting width Wa according to the wettability of the droplet 20 with respect to the landing surface 11a, and the organic EL layer 15 can be formed in a uniform shape. As a result, the productivity of the organic EL display 1 can be increased.

(2) With the above embodiment, the surface of the droplet 20 was made to approximate a spherical surface, and the thickness of the droplet 20 from the landing surface 11a when the surface of the droplet 20 reached the apex of the barrier 14 (the maximum allowable droplet thickness Hmx) was found from the shape of the organic EL layer formation region S (the wetting width Wa, the barrier width Wb, and the barrier thickness Hb) and the barrier contact angle θb. The upper limit volume of the droplet 20 to be discharged into the organic EL layer formation region S was determined on the basis of the maximum allowable droplet thickness Hmx, and the volume (target volume) of the droplet 20 to be discharged into the organic EL layer formation region S was set to be less than or equal to this upper limit volume.

Therefore, leakage of the droplet 20 into adjacent organic EL layer formation regions S can be avoided according to the wettability of the droplet 20 with respect to the landing surface 1 I a, and the volume of the droplet 20 formed in each organic EL layer formation region S can be more uniform. As a result, the organic EL layer 15 can be formed in a uniform shape, and the productivity of the organic EL display 1 can be increased.

(3) With the above embodiment, the receptacle hole 13 was formed in a circular shape, and the wetting width Wa was set to be the inside diameter of the receptacle hole 13 on the landing surface 11a side. The lower limit volume was then determined on the basis of this wetting width Wa. Therefore, the discharged droplet 20 is able to wet and spread out over the entire landing surface 11 a, and the organic EL layer 15 can be formed in a uniform shape.

(4) With the above embodiment, the landing surface 11 a was rendered lyophilic and the barrier 14 was rendered liquid-repellent. Therefore, the wettability of the droplet 20 with respect to the landing surface 11a can be increased, and the ability of the organic EL layer formation region S to accommodate the droplet 20 can also be increased. Furthermore, since the volume (target volume) of the droplet 20 is determined according to the contact angle of the droplet with respect to the landing surface 11a and the barrier 14, the droplet 20 can be discharged in a volume suited to the organic EL layer formation region S, and the organic EL layer 15 can be formed in a more uniform shape.

The above embodiment may be modified as follows.

In the above embodiment, the surface of the droplet 20 was made to approximate a spherical surface, the minimum allowable droplet thickness Hmn was set at (Wa+Wb)·{(1−cos θb)/sin θb}+Hb, and the maximum allowable droplet thickness Hmx was set at Wa·{(1−cos θa)/sin θa}, but other options are also possible. For example, the surface of the droplet 20 may approximate an aspherical surface, and the minimum allowable droplet thickness Hmn and maximum allowable droplet thickness Hmx can be found on the basis of the wetting width Wa, the barrier width Wb, the barrier thickness Hb, the landing surface contact angle θa, and the barrier contact angle θb.

In the above embodiment, the pattern, the pattern formation side, and the pattern formation region were embodied by the organic EL layer 15, the landing surface 11a, and the organic EL layer formation region S, respectively, and the organic EL display 1 was manufactured by forming the droplet 20 containing an organic EL layer formation material in the organic EL layer formation region S, but other options are also possible.

For example, the pattern and the pattern formation side may be embodied by a colored color filter layer and a single side of the transparent substrate 2, respectively, and the pattern formation region may be constituted as a color filter layer formation region by forming the barrier 14 for forming a color filter layer on this one side.

In other words, this may be a pattern formation method in which a pattern is formed by forming droplets containing a pattern formation material in pattern formation regions surrounded by barriers on the pattern formation side, and the volume (target volume) of these droplets may be determined on the basis of the landing surface contact angle θa and barrier contact angle θb of the droplets.

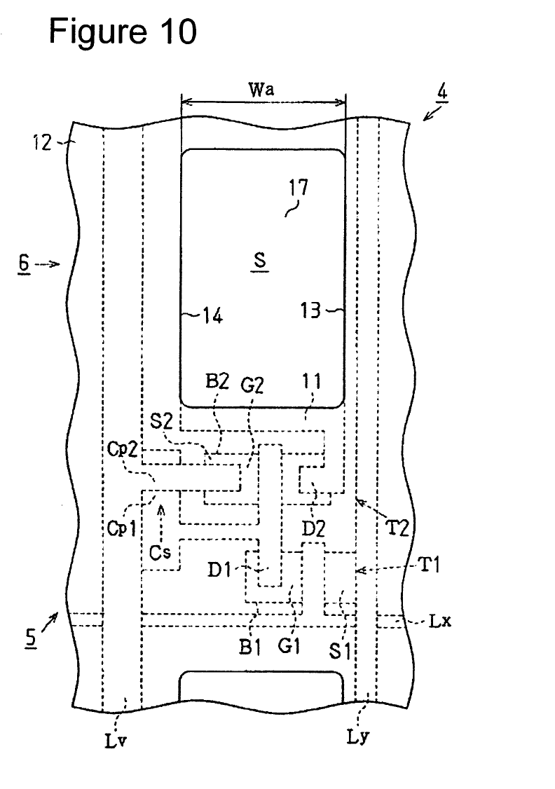

In the above embodiment, the receptacle hole 13 was embodied as a circular hole, but is not limited to this, and may, for example, be embodied as a rectangular hole as shown in FIG. 10.

Here, if the wetting width Wa is facing in the minor axis direction of the organic EL element 17, the droplet 20 will be able to wet and spread out over at least the entire width in the minor axis direction. If a plurality of droplets 20 are formed in the major axis direction, the organic EL layer 15 can be formed in a uniform shape over the entire landing surface 11a. In other words, it is preferable to select the direction in which the wetting width Wa and the barrier width Wb are set on the basis of the direction in which the droplets 20 are formed (such as the above-mentioned major axis direction).

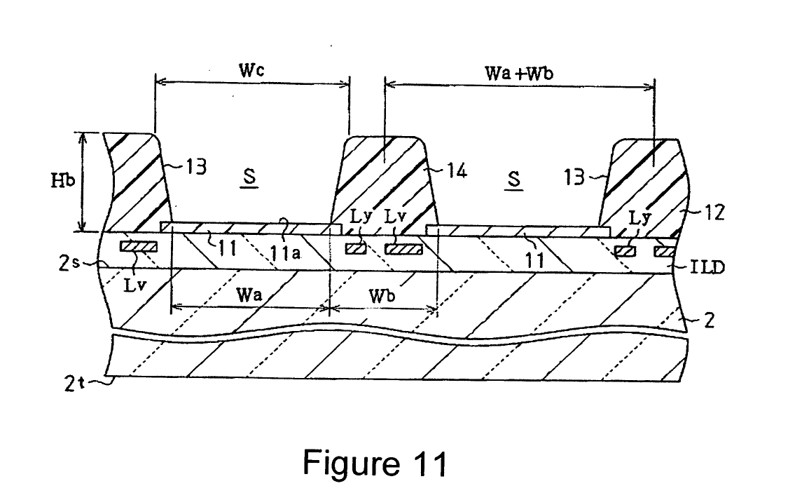

In the above embodiment, the barrier 14 was formed in an arced cross sectional shape, but is not limited to this, and may instead be formed in a trapezoidal cross sectional shape as shown in FIG. 11, for example.

It is preferable here if the inside diameter Wc on the upper side of the receptacle hole 13 (the opposite side from the anode 11) is formed at a predetermined value, the same as the wetting width Wa, in order to determine the upper limit volume. This allows the upper limit volume to be determined more accurately, and allows the uniformity of the shape of the patter (the organic EL layer 15) to be further improved.

In the above embodiment, the barrier 14 was constituted as the barrier layer 12 alone, but is not limited to this, and instead, for example, a lyophilic layer that is lyophilic to the droplets 20 may be formed on the anode 11 side, and a liquid-repellent layer that repels the droplets 20 may be formed over this lyophilic layer, so that the barrier layer 12 composed of two layers.

This allows the droplets 20 to wet and spread out over the landing surface 11a side (lower side) of the barrier 14, and allows the droplets 20 to be repelled on the upper side of the barrier 14. Therefore, the wettability with respect to the landing surface 11a can be increased, and leakage of the droplets 20 can be effectively avoided.

In the above embodiment, the control element formation region 5 was equipped with the switching transistor T1 and the drive transistor T2, but is not limited to this, and the constitution may instead be such that a single transistor, or numerous transistors, or numerous capacitors are used, according to the desired element design.

In the above embodiment, the microscopic lower layer droplets Ds were discharged by the piezoelectric elements 29, but the present invention is not limited to this, and a resistance heating element may be provided to the functional liquid supply chamber 27, for example, and the microscopic lower layer droplets Ds may be discharged by bursting the bubbles formed by the heating of this resistance heating element.

In the above embodiment, the electro-optical device was embodied as the organic EL display 1, but is not limited to this, and may instead be a liquid crystal panel, for example, or may be a field effect type of display (FED, SED, etc.) that is equipped with a flat electron emission element, and that utilizes the ability of a fluorescent substance to emit light as a result of the electrons emitted from this element.

This application claims priority to Japanese Patent Application No. 2005-003423. The entire disclosure of Japanese Patent Application No. 2005-003423 is hereby incorporated herein by reference.

What is claimed is:

1. A pattern formation method, comprising:
forming on a pattern formation surface a barrier for forming a pattern; and
discharging in a pattern formation region bounded by the barrier droplets containing a pattern formation material, thereby forming the pattern;
wherein a lower limit volume of the droplet is determined based on a width in one direction of the pattern formation region and a contact angle of the droplets with respect to the pattern formation surface, such that a volume of the droplet discharged in the pattern formation region is equal to or greater than the lower limit volume.

2. The pattern formation method according to claim 1, wherein
the lower limit volume is a volume at which a distance between an apex of the droplet discharged in the pattern formation region and the pattern formation surface is expressed as: Wa·{(1−cos θa)/sin θa}
where Wa is the width of the pattern formation region in the one direction, and θa is the contact angle of the droplets with respect to the pattern formation surface.

3. The pattern formation method according to claim 1, wherein
the pattern formation surface is rendered lyophilic with respect to the droplets.

4. A pattern formation method, comprising:
forming on a pattern formation surface a barrier for forming a pattern; and
discharging in a pattern formation region bounded by the barrier droplets containing a pattern formation material, thereby forming the pattern,
wherein an upper limit volume of the droplet is determined based on a width of the pattern formation region in one direction, a width of the barrier in the one direction, a distance between the pattern formation surface and an apex of the barrier, and a contact angle of the droplets with respect to the barrier, and
a volume of the droplet discharged in the pattern formation region is equal to or less than the upper limit volume.

5. The pattern formation method according to claim 4, wherein,
the upper limit volume is a volume at which a distance between an apex of the droplet discharged in the pattern formation region and the pattern formation surface is (Wa+Wb)·{(1−cos θb)/sin θb}+Hb,
where Wa is the width of the pattern formation region in the one direction, Wb is the width of the barrier in the one direction, Hb is a thickness of the barrier from the pattern formation side, and θb is the contact angle of the droplets with respect to the pattern formation surface.

6. The pattern formation method according to claim 4, wherein
the barrier is rendered liquid-repellent with respect to the droplets.

7. A pattern formation method, comprising:
forming on a pattern formation surface a barrier for forming a pattern; and
discharging in a pattern formation region bounded by the barrier droplets containing a pattern formation material, thereby forming the pattern,
wherein a lower limit volume of the droplet is determined based on a width of the pattern formation region in a first direction and a contact angle of the droplets with respect to the pattern formation side,
an upper limit volume of the droplet is determined based on a width of the pattern formation region in a second direction, a width of the barrier in the second direction, a distance between the pattern formation surface and an apex of the barrier, and a contact angle of the droplets with respect to the barrier, and
a volume of the droplet discharged in the pattern formation region is equal to or greater than the lower limit volume, and equal to or less than the upper limit volume.

8. A pattern formation method, comprising:
forming on a pattern formation surface a barrier for forming a pattern; and
discharging in a pattern formation region bounded by the barrier droplets containing a pattern formation material, thereby forming the pattern,
wherein each of the droplets is discharged in the pattern formation region in a volume that satisfies
Wa{(1−cos θa)/sin θa}≦H≦(Wa+Wb)·{(1−cos θb)/sin θb}+Hb
where Wa is a width of the pattern formation region in one direction, Wb is a width of the barrier in the one direction, Hb is a thickness of the barrier from the pattern formation surface, θb is a contact angle of the droplets with respect to the pattern formation surface, and H is a distance between an apex of the droplet discharged in the pattern formation region and the pattern formation surface.

9. A method for manufacturing a color filter, in which a color filter layer is formed on a transparent substrate,
wherein the color filter layer is formed by the pattern formation method according to claim 1.

10. A color filter, manufactured by the method for manufacturing a color filter according to claim 9.

11. A method for manufacturing an electro-optical device, in which a light emitting element is formed on a transparent substrate,
wherein the light emitting element is formed by the pattern formation method according to claim 1.

12. An electro-optical device, manufactured by the method for manufacturing an electro-optical device according to claim 11.
